(19) United States
(12) Patent Application Publication
(10) Pub. No.: US 2007/0085132 A1
(43) Pub. Date: Apr. 19, 2007

(54) Semiconductor memory device and method for producing same

(75) Inventors: Kazuhiko Sanada, Kanagawa (JP); Kohji Kanamori, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC ELECTRONICS CORPORATION, KANAGAWA (JP)

(21) Appl. No.: 11/546,954

(22) Filed: Oct. 13, 2006

(30) Foreign Application Priority Data
Oct. 18, 2005 (JP) 2005-303387

(51) Int. Cl. H01L 29/788

(52) U.S. Cl. 257/315

(57) ABSTRACT

A semiconductor memory device with improved operational reliability, and a method for fabricating the device. The semiconductor memory device includes a select gate 3a, arranged in a first area on a substrate 1, floating gates 6a arranged in a second are,a adjacent to the first area, first and second diffusion areas 7a, 7b arranged in a third area adjacent to the second area, and a control gate 11 arranged on the top of the floating gates 6a. The upper end faces of the floating gates 6a are planarized.

### FIELD OF THE INVENTION

This invention relates to a semiconductor memory device including a plural number of cell transistors, and a method for producing the device. More particularly, this invention relates to a semiconductor memory device for holding the information of a plural number of bits per cell, and to a method for producing the memory device.

### BACKGROUND OF THE INVENTION

As a conventional semiconductor memory device, there is known a non-volatile semiconductor memory device having a plural number of cell transistors shown in FIG. 8 (Example 1 of the related art). The non-volatile semiconductor memory device of Example 1 of the related art is an AND flash memory including a plural number of non-volatile memory cells. These memory cells are each made up of a plural number of first electrodes 104G, a plural number of word lines 105, arranged for intersecting the first electrodes, and a plural number of floating gate electrodes 106G. Each floating gate electrode is arranged in an area where the floating gate electrode is horizontally overlapped with the word line 105 between neighboring ones of the first electrodes 104G. Each of the floating gate electrodes 106G is of a convexed (or protruding) cross-sectional shape larger in height than the first electrode 104G (see Patent Document 1).

The method for producing the non-volatile semiconductor memory device of the Example 1 of the related art includes the following steps. That is, a conductor film for forming a first electrode 104G is deposited in step (a) via a first insulating film 108 on a semiconductor substrate 101S. A second insulating film 110 is deposited in step (b) on the conductor film adapted for forming the first electrode 104G. A third insulating film, not shown, is deposited on the second insulating film 110 in step (c). The conductor film for forming the first electrode 104G, the second insulating film 110 and a third insulating film, not shown, are then patterned, in step (d), to form a layered pattern of the first electrode 104G, second insulating film 110 and the third insulating film, not shown. A fourth insulating film 116 is then formed in step (e) on lateral sides of the first electrode 104G. A fifth insulating film 115 is then formed on the semiconductor substrate 101S between neighboring ones of the layered patterns of the first electrodes 104G, second insulating films 110 and the third insulating films, not shown, in step (f). A conductor film for forming a third electrode 106G is then deposited for filling in the space between the neighboring ones of the layered patterns of the first electrodes 104G, second insulating films 110 and the third insulating films, not shown, in step (g). The conductor film for forming a third electrode 106G is then removed by etchback with anisotropic dry etching or by chemical mechanical polishing so that the conductor film for forming the third electrode 106G will be left between neighboring ones of the layered patterns of the first electrodes 104G, second insulating films 110 and the third insulating films, not shown, in step (h). In this step, a pattern of the conductor film for forming the third electrode 106G is formed between the neighboring ones of the layered patterns of the first electrodes 104G, second insulating films 110 and the third insulating films, not shown, in a self-aligned fashion with respect to the first electrode 104G. The third insulating films, not shown, are then removed, in step (i). A sixth insulating film 118 is then deposited in step (j) on the semiconductor substrate 101S. A conductor film for forming a second electrode 105 is then deposited in step (k) on the sixth insulating film 118. The conductor film for forming a second electrode 105 is then patterned in step (1) to form a plural number of the second electrodes 105. The conductor film for forming a third electrode 106G is then patterned, in step (m), using the plural second electrodes 105, as masks, to form a plural number of the third electrodes 106G of a convexed cross-sectional shape and a height larger than the height of the first electrodes 104G, in a self-aligned fashion with respect to the plural second electrodes 105.

There is also known a non-volatile semiconductor memory device, shown in FIGS. 9 and 10, as a conventional semiconductor memory device (Example 2 of the related art). This conventional semiconductor memory device (Example 2 of the related art) includes a first diffusion area 207a and a second diffusion area 207b, arranged side-by-side in a spaced-apart relation to each other, on the surface of a substrate 201. The semiconductor memory device also includes a select gate 203a, arranged on the substrate 201 in an area between the first diffusion area 207a and the second diffusion area 207b, with an insulating film 202 in-between. The semiconductor memory device also includes third diffusion areas (221 of FIG. 9) arranged on a surface of the substrate 201 below the select gate 203a outside the cell area for extending in a direction of intersecting the select gate 203a. The semiconductor memory device further includes floating gates 206a and control gates 211 each arranged over the floating gates 206a with an insulating film 208 in-between. The floating gates 206a are arranged in a first area defined between the first diffusion area 207a and the select gate 203a, with the interposition of an insulating film 205, and in a second area defined between the second diffusion area 207b and the select gate 203a, with the interposition of the insulating film 205. The first diffusion area 207a, floating gate 206a, control gate 211 and the select gate 203a make up a first unit cell, and the second diffusion area 207b, floating gate 206a, control gate 211 and the select gate 203a make up a second unit cell (see Patent Document 2). An inverted layer 220 is formed on the surface of the substrate 201 below the select gate 203a in the cell area by a positive voltage applied to the select gate 203a.

With the non-volatile semiconductor memory device of Example 2 of the related art, as contrasted to the non-volatile semiconductor memory device of the aforementioned Example 1, the memory node of a target unit cell, which is independent of and separated from the non-target memory node of a unit cell, with the select gate 203a in-between, is read out with the channel below the select gate 203a as a drain, without the intermediary of the non-target memory node of the unit cell. This constitution of the non-volatile semiconductor memory device of Example 2 of the related art is effective to raise the density of the memory cells and to reduce the device size.

The method for producing the non-volatile semiconductor memory device of Example 2 of the related art will now be described with reference to the drawings. FIGS. 11A to 14L are cross-sectional views for illustrating the non-volatile semiconductor memory device of Example 2 of the related art.

Initially, a device isolation area, not shown, is formed in the substrate 201. A well, not shown, is then formed in a cell area of the substrate 201 and subsequently a third diffusion area (221 of FIG. 9) is formed. The insulating film 202, e.g. a silicon oxide film, then is formed on the substrate 201. A select gate film 203, such as a polysilicon film, then is formed on the insulating film 202, and an insulating film 204, such as a silicon nitride film, is formed on the select gate film 203. An insulating film 212, such as a silicon oxide film, then is formed on the insulating film 204, and an insulating film 213, such as a silicon nitride film, then is formed on the insulating film 212 (step A1 of FIG. 11A). A photoresist, not shown, for forming the select gate 203a, then is formed on the insulating film 213. Using the photoresist as a mask, the insulating films 213, 212 and 204, the select gate film (203 of FIG. 11A) and the insulating film 202 are selectively etched to form the select gate 203a. Subsequently, the photoresist is removed in step A2 of FIG. 11B. An insulating film 205, such as a silicon oxide film, then is formed on exposed surfaces of the substrate 201 and the select gate 203a, in step A3 of FIG. 11C.

A floating gate film 206, such as a polysilicon film, is then formed on the entire substrate surface, in step A4 of FIG. 12D. The floating gate film (206 of FIG. 12D) then is etched back to form a sidewall-like floating gate 206a on sidewall sections of the select gate 203a and the insulating films 204, 212 and 213, in step A5 of FIG. 12E. The first diffusion area 207a and the second diffusion area 207b are then formed in self-aligned fashion by ion implantation in the substrate 201, with the insulating film 213 and the floating gates 206a as masks, in step A6 of FIG. 12F.

An insulating film 209, such as a CVD silicon oxide film, then is deposited on the entire substrate surface in step A7 of FIG. 13G. The insulating film 209 then is planarized, by the CMP method, using the insulating film 213 as a stopper, in step A8 of FIG. 13H. The insulating film 209 then is selectively removed in part in step A9 of FIG. 13I.

The insulating film (213 of FIG. 131) then is selectively removed in step A10 of FIG. 14J. The insulating film 212, inclusive of part of the insulating film 209, then is selectively removed in step All in FIG. 14K. In removing the insulating film 212, part of the insulating film 209 is also removed. The insulating film 208, such as an ONO film, then is formed on the entire substrate surface, in step A12 of FIG. 14L.

A control gate film, such as a polysilicon film, is then deposited on the entire substrate surface to form a photoresist, not shown, which is adapted for forming a word line. Using the photoresist as a mask, the control gate film, insulating film 208 and the floating gate film 206 are selectively removed to form band-shaped control gates 211 and island-shaped floating gates 206a. The photoresist is then removed in step A13 (see FIG. 10). This completes a semiconductor memory device having memory cells.

Referring to the drawings, the readout operation by the non-volatile semiconductor memory device of Example 2 of the related art will be explained. FIG. 15 depicts a schematic view for illustrating the readout operation of the semiconductor memory device of Example 2 of the related art, that is, the readout operation for a state in which no electrons have been accumulated in the floating gates.

Reference is made to FIG. 15 for illustrating the readout operation. If, in a state where no electrons have been accumulated in the floating gate 206a (erased state; low threshold voltage; cell ON), a positive voltage is applied to the control gate 211, select gate 203a and to the third diffusion area (221 of FIG. 9), electrons will flow from the second diffusion area 207b through a channel directly below the floating gate 206a, and through an inverted layer 220 formed below the select gate 203a, to get to the third diffusion area (221 of FIG. 9). Conversely, if, in a state where electrons have been charged in the floating gate 206a (recorded state; high threshold voltage; cell OFF), a positive voltage is applied to the control gate 211, select gate 203a and to the third diffusion area (221 of FIG. 9), no electron flow occurs because there is no channel below the floating gate 206a, in a manner not shown. Readout may be made possible by verifying data (0/1) depending on whether or not there occurs the flow of electrons e.

[Patent Document 1]

Japanese Patent Kokai Publication No. JP-P2005-85903A

[Patent Document 2]

US 2005/0029577 A1

[Patent Document 3]

Japanese Patent Kokai Publication No. JP-A-11-354742

### SUMMARY OF THE DISCLOSURE

In the method for producing the non-volatile semiconductor memory device of Example 2 of the related art, the floating gates 206a are formed by etchback (see FIG. 12E) and hence are shaped like sidewalls. Consequently, each floating gate has a steep angular edge 206b at an upper end thereof towards the sidewall surface of the insulating film 204 (see FIG. 10). In case the floating gate 206a has such angular edge, the low voltage, applied to the control gate 211 at the time of the readout operation, generates an electrical field concentrated at the angular edge of the floating gate 206a (see FIG. 16), with a result that electrons are extracted from the floating gate to the control gate (see FIG. 17). Moreover, since the floating gate 206a is subjected to variations in the etchback (see FIG. 12E), there is fear that the floating gate 206a tends to be varied in its shape and height, more precisely, in the position of the angular edge 206b. In particular, the vicinity of an upper edge of a sidewall-shaped curved surface of the floating gate 206a is more susceptible to variations in etchback, and hence to damages caused by the etchback, than the vicinity of the lower edge thereof, with a consequence that the device may be lowered in operational reliability.

It is a principal object of the present invention to provide a semiconductor memory device improved in operational reliability.

In one aspect, the present invention provides a method for producing a semiconductor memory device including the following steps: forming a sidewall-shaped floating gate at a sidewall of a select gate on a substrate, via an insulating film, and planarizing an upper end of the floating gate.

In the above-described method for producing a semiconductor memory device, each one of a plurality of the select gates is formed via a first insulating film on the substrate in the floating gate forming step; and second, third, fourth and fifth insulating films are formed in this order on each one of the select gates when looking from the bottom towards above. A second semiconductor film is deposited on a sixth insulating film formed in an area of the substrate defined between two neighboring ones of the select gates and on sidewall surfaces of the two neighboring ones of the select gates. A plurality of sidewall-shaped floating gates are formed by etchback on both sides of at least the fifth, fourth, third and second insulating films and on both sides of the select gates. The fifth insulating film is removed in the step of planarizing the upper ends of the floating gates.

The method for producing a semiconductor memory device according to the present invention includes, before the forming step of the floating gates, forming a first insulating film, a first semiconductor film, a second insulating film, a third insulating film, a fourth insulating film and a fifth insulating film, on the substrate, in this order, when looking from the bottom towards above; selectively etching the fifth insulating film, fourth insulating film, third insulating film, second insulating film and the first insulating film, in a preset area, to form the select gate; and forming the sixth insulating film at least in an area of the substrate defined between neighboring ones of the select gates and on sidewall surfaces of the select gates. The method for producing a semiconductor memory device according to the present invention also includes, between the forming step of the floating gates and the planarizing step of the upper ends of the floating gates, forming self-aligned first and second diffusion areas, on the surface of the substrate, by ion implantation, using the fifth insulating film and the floating gate as masks; and embedding a seventh insulating film in an area between the neighboring ones of the floating gates, on the top of the first and second diffusion areas. The method farther includes, after the planarizing step of the upper end of the select gate, removing the fourth insulating film and the third insulating film; forming an eighth insulating film on the entire substrate surface; and forming a control gate on the eighth insulating film.

In the method for producing a semiconductor memory device, according to the present invention, the upper end faces of the seventh insulating film and the floating gate are preferably planarized by a CMP method, in the planarizing step of the upper end of the floating gate, with the fourth insulating film as a CMP stopper.

In another aspect of the present invention, there is provided a semiconductor memory device comprising: a select gate arranged in a first area on a substrate; first and second floating gates arranged in a second area adjacent to the first area; first and second diffusion areas arranged in a third area adjacent to the second area; and a control gate arranged on the top of the first and second floating gates. The upper end faces of the first and second floating gates are planarized.

In the semiconductor memory device, according to the present invention, the first and second floating gates preferably include sidewall surfaces formed by etchback. The upper end faces of the first and second floating gates are planarized preferably by CMP.

The meritorious effects of the present invention are summarized as follows.

According to the present invention, as defined in the claims, in which the upper end faces of the floating gates are planarized, the eighth insulating film is improved in operational reliability. Moreover, the variations in the cross-sectional shape and the height of the floating gates, ascribable to the etchback, may be decreased to significantly reduce the variations in the cell capacitance ratio otherwise caused by manufacture tolerances. In addition, since the upper end faces of the floating gates are planarized, there is no fear of the electrical field becoming concentrated in a space between the floating gate and the control gate, even on application of a readout voltage on the control gate, so that no electrons are extracted from the floating gate 6a, and hence the operational reliability is improved.

### BRIEF DESCRIPTION OF THE DRAWINGS

FIG. 1 is a partial plan view schematically showing the constitution of a semiconductor memory device according to a first embodiment of the present invention.

FIG. 2 is a partial cross-sectional view, taken along line X-X of FIG. 1, schematically showing the constitution of the semiconductor memory device according to the first embodiment of the present invention.

FIGS. 3A, 3B and 3C are cross-sectional views schematically showing process steps of a method for producing the semiconductor memory device according to the first embodiment of the present invention.

FIGS. 4D, 4E and 4F, continuing to FIGS. 3A to 3C, are cross-sectional views schematically showing process steps of the method for producing the semiconductor memory device according to the first embodiment of the present invention.

FIGS. 5G, 5H and 5I, continuing to FIGS. 4D to 4F, are cross-sectional views schematically showing process steps of the method for producing the semiconductor memory device according to the first embodiment of the present invention.

FIGS. 6J, 6K and 6L, continuing to FIGS. 5G to 5I, are cross-sectional views schematically showing process steps of the method for producing the semiconductor memory device according to the first embodiment of the present invention.

FIG. 7 is a schematic view for illustrating the state of an energy band between the control gate and the floating gate of the semiconductor memory device according to the first embodiment of the present invention.

FIG. 8 is a partial cross-sectional view schematically showing the constitution of a semiconductor memory device according to Example 1 of the related art.

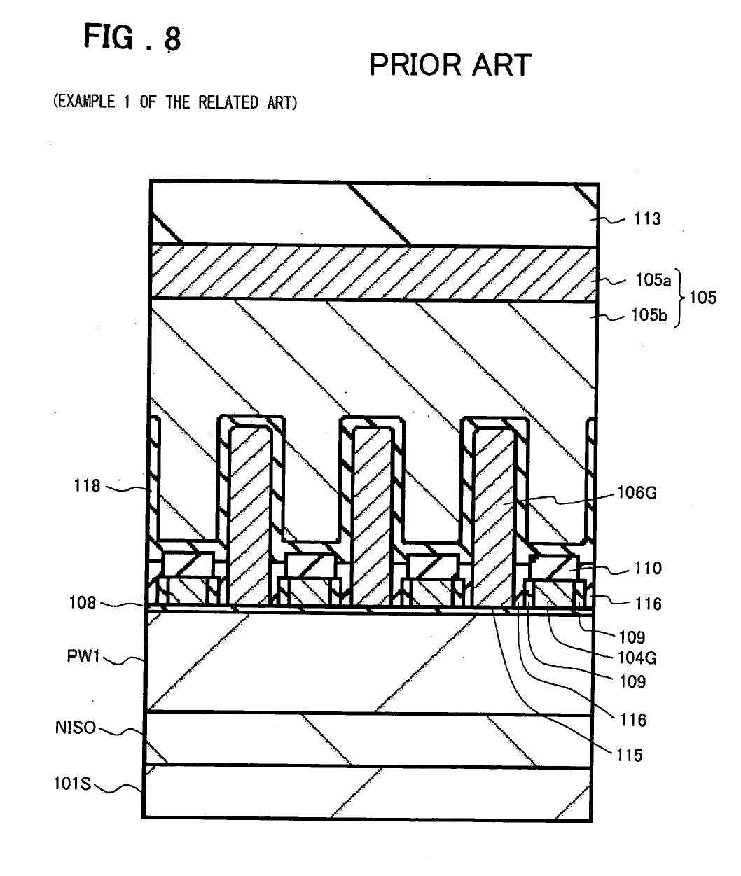

FIG. 9 is a partial plan view schematically showing the constitution of a semiconductor memory device according to Example 2 of the related art.

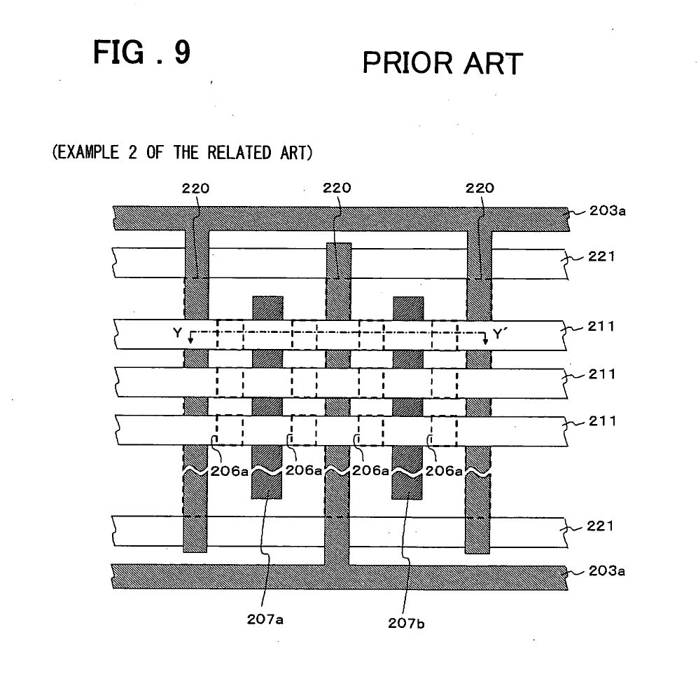

FIG. 10 is a partial cross-sectional view, taken along line Y-Y′ of FIG. 9, schematically showing the constitution of the semiconductor memory device according to Example 2 of the related art.

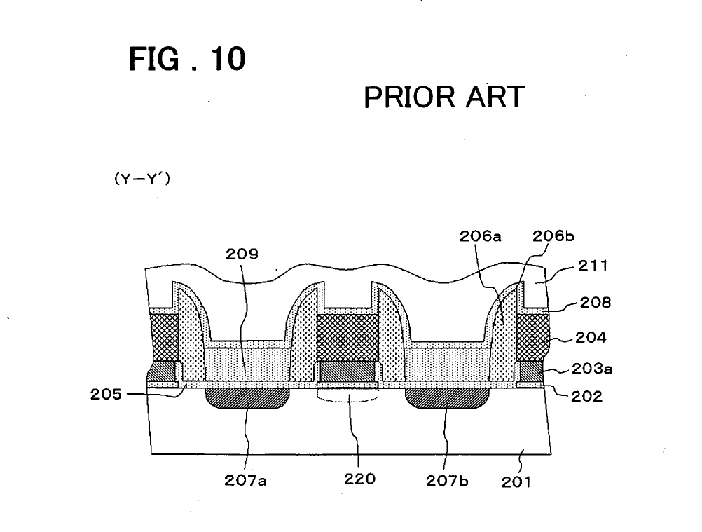

FIGS. 11A, 11B and 11C are cross-sectional views schematically showing process steps of a method for producing the semiconductor memory device according to Example 2 of the related art.

FIGS. 12D, 12E and 12F, continuing to FIGS. 11A to 11C, are cross-sectional views schematically showing process steps of the method for producing the semiconductor memory device according to Example 2 of the related art.

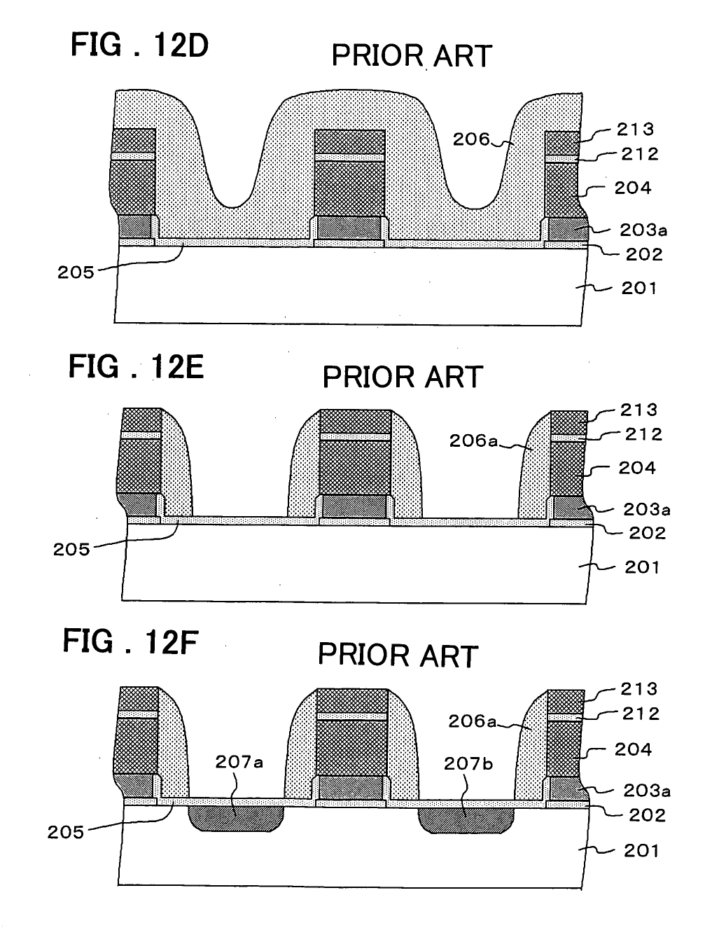

FIGS. 13G, 13H and 13I, continuing to FIGS. 12D to 12F, are cross-sectional views schematically showing process steps of the method for producing the semiconductor memory device according to Example 2 of the related art.

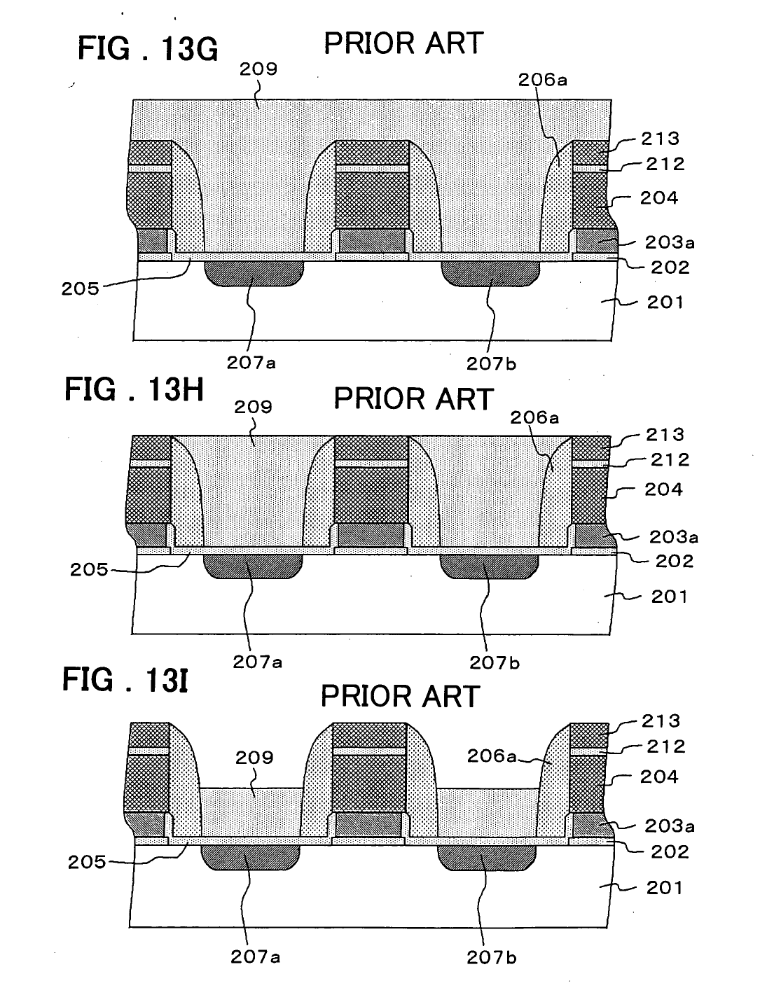

FIGS. 14J, 14K and 14L, continuing to FIGS. 13G to 13I, are cross-sectional views schematically showing process steps of the method for producing the semiconductor memory device according to Example 2 of the related art.

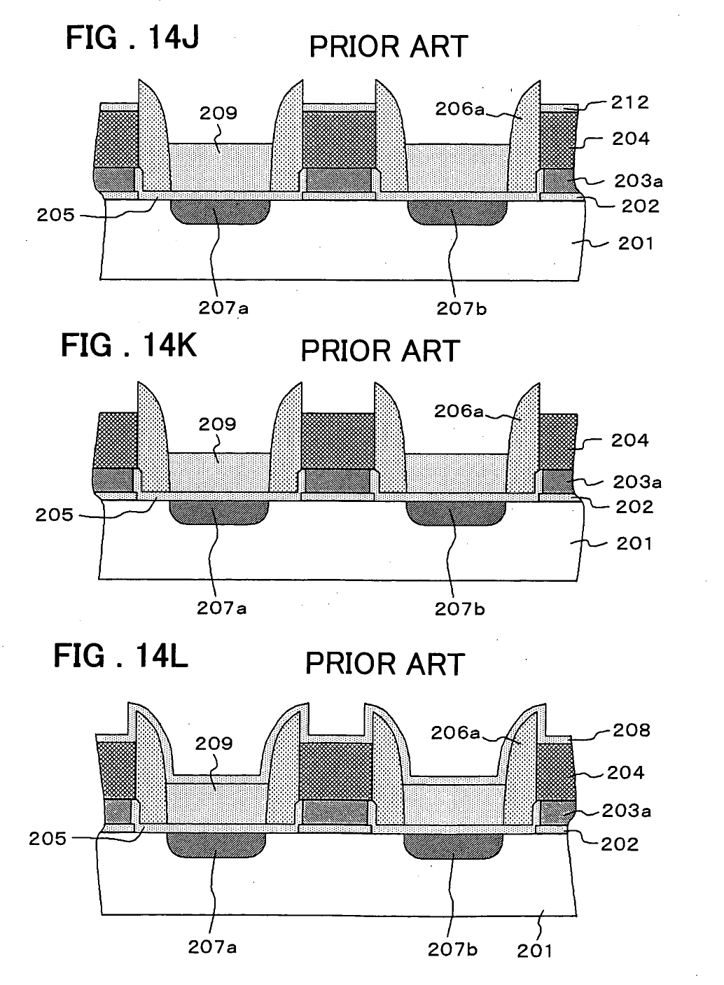

FIG. 15 is a schematic cross-sectional view for illustrating the readout operation of the semiconductor memory device according to Example 2 of the related art (readout operation in a state where no electrons have been accumulated in the floating gate).

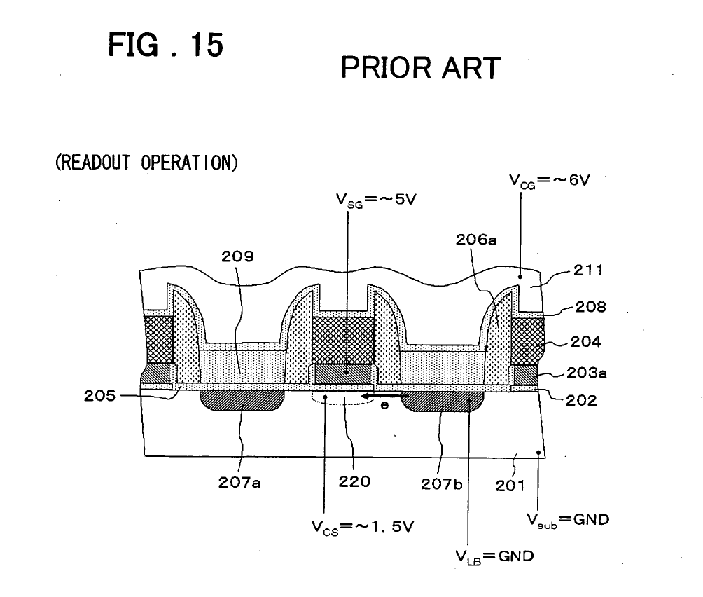

FIG. 16 is a schematic view for illustrating the state of the electrical field between the control gate and the floating gate of the semiconductor memory device according to Example 2 of the related art.

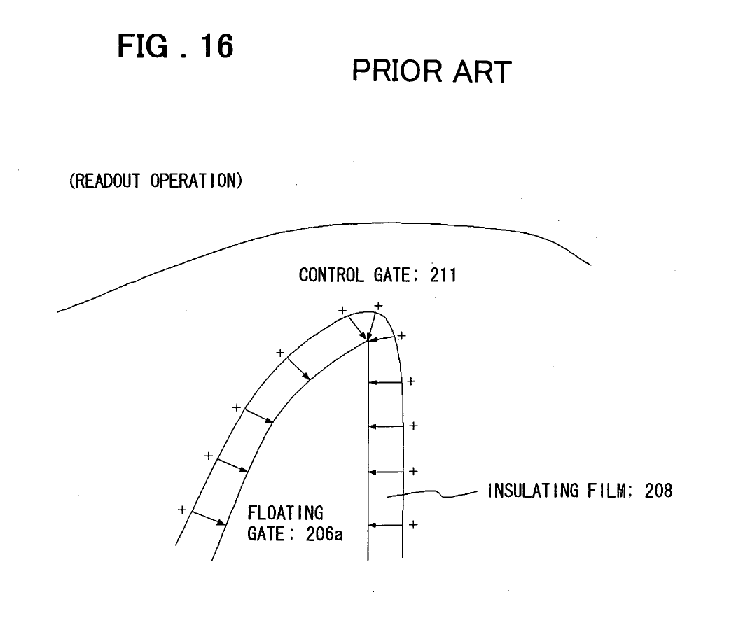

FIG. 17 is a schematic view for illustrating the state of an energy band between the control gate and the floating gate of the semiconductor memory device according to Example 2 of the related art.

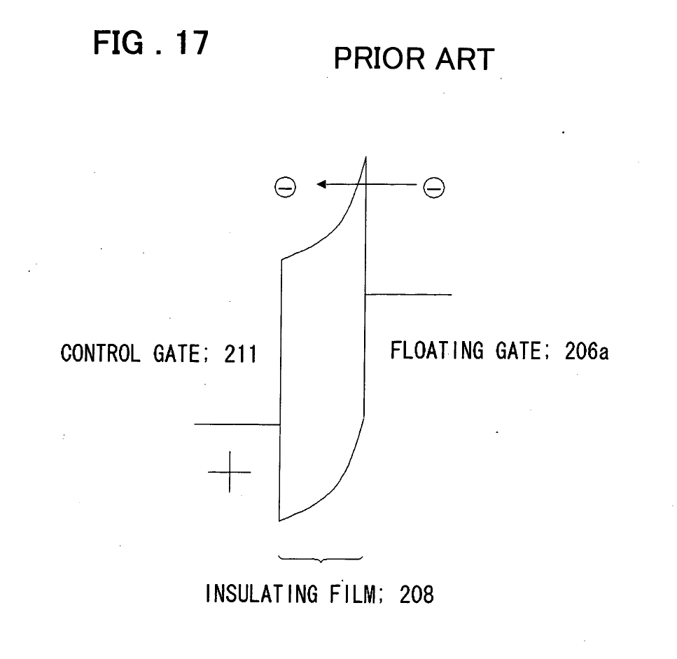

### PREFERRED EMBODIMENTS OF THE INVENTION

### First Embodiment

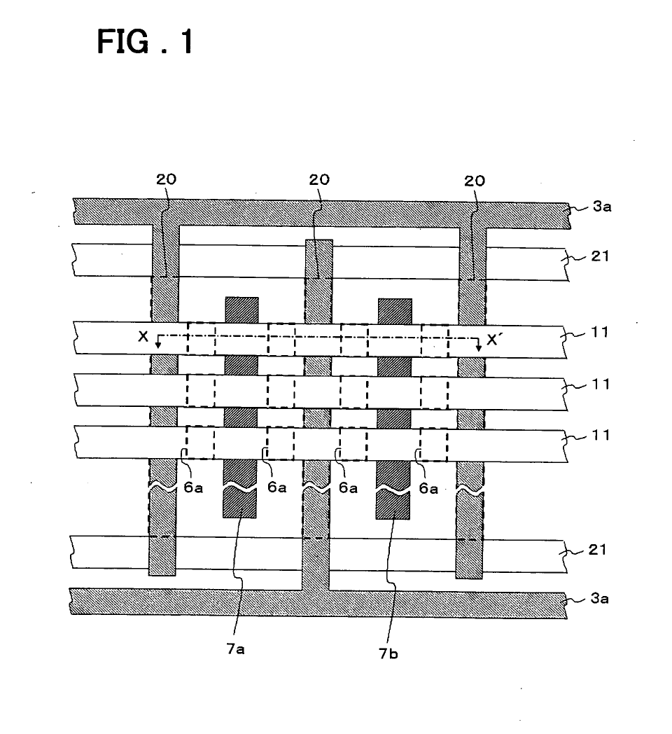

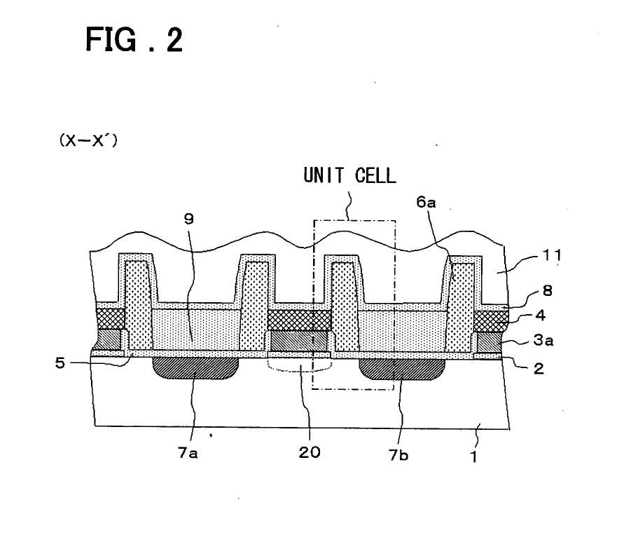

A semiconductor memory device according to a first embodiment of the present invention will now be described with reference to the drawings. FIG. 1 depicts a schematic partial plan view showing the constitution of a semiconductor memory device according to the first embodiment of the present invention, and FIG. 2 is a partial cross-sectional view, taken along line X-X of FIG. 1, schematically showing the constitution of the semiconductor memory device according to the first embodiment of the present invention.

The semiconductor memory device of the present first embodiment is a non-volatile semiconductor memory device for storing two bits of the information per cell. The semiconductor memory device includes a substrate 1, an insulating film 2, a plural number of select gates 3a, an insulating film 4, an insulating film 5, floating gates 6a, a first diffusion area 7a, a second diffusion area 7b, an insulating films 8, an insulating film 9, a plural number of control gates 11 and a plural number of third diffusion areas 21 (see FIGS. 1 and 2). In this semiconductor memory device, a unit cell is made up of the sole second diffusion area 7b (or the sole first diffusion area 7a), the sole floating gate 6a, the control gate 11 and a select gate 3a, e.g., as indicated by a chain-dotted line in FIG. 1. A 2-bit cell in the semiconductor memory device is formed by arranging two of such unit cells with linear symmetry, with the select gate 3a being used in common.

The substrate 1 is a P-type silicon substrate (see FIGS. 1 and 2). The insulating film 2 is a select gate insulating film, such as a silicon oxide film, provided between the select gate 3a and the substrate 1 (see FIG. 2).

The select gate 3a is an electrically conductive film of, for example, polysilicon, provided on the insulating film 2 (see FIGS. 1 and 2). When viewed from the direction of a line normal to the plane, the select gate 3a includes a plural number of comb-tooth-like protrusions (bands) extending from a common line (a horizontal line of FIG. 1). The comb-tooth-like protrusions (bands) of one of the select gates 3a are arranged to interdigitate with those of the other select gate 3a, that is, the comb-tooth-like protrusions (bands) of the select gates 3a, 3a are arranged to mesh with one another with a preset interval between the neighboring comb-tooth-like protrusions (bands).

The insulating film 4 is an insulating film of, for example, silicon nitride, provided on the select gate 3a (see FIG. 2). The insulating film 5 is a tunnel insulating film, such as a silicon oxide film, arranged at least in contact with the sidewall section of the select gate 3a, substrate 1 and the floating gate 6a.

The floating gate 6a is a storing node provided on both sides of the select gate 3a with the interposition of the insulating film 5 (see FIGS. 1 and 2). The floating gate 6a may be formed of, for example, polysilicon. The sidewall surface of the floating gate 6a is a surface formed to a sidewall-like shape by etchback and which is approximately orthogonal to the upper surface, that is, the upper major surface, of the substrate 1. The upper end surface of the floating gate 6a has been planarized by CMP (see FIG. 2). The upper end surface of the floating gate 6a is substantially parallel to the upper surface, that is, the upper major surface, of the substrate 1. The upper end surface of the floating gate 6a has been flattened to an even height. When viewed from a direction normal to the plane, the floating gates 6a are formed in the form of islands (see FIG. 1).

The first diffusion area 7a and the second diffusion area 7b are each an n⁺ diffusion area provided at preset locations of the substrate 1, that is, between neighboring ones of the floating gates 6a, and are arranged along the direction of extension of the select gate 3a, more correctly, along the direction of extension of the comb-tooth-like protrusions (bands) thereof (see FIGS. 1 and 2). The first diffusion area 7a and the second diffusion area 7b operate as drain areas or as source areas of the cell transistor, during writing or readout, respectively, in relation to the select gate 3a. The first diffusion area 7a and the second diffusion area 7b are also termed local bit lines. The concentration of impurities of the first diffusion area 7a is set so as to be equal to that of the second diffusion area 7b.

The insulating film 8 is provided between the floating gates 6a and the control gates 11, and may, for example, be an ONO film, which is formed of silicon oxide, silicon nitride or silicon oxide, which is high in insulating properties and in dielectric constant and which lends itself to reducing the film thickness (see FIG. 2). The insulating film 9 is provided between the insulating film 8 and the substrate 1, more precisely, the first diffusion area 7a and the second diffusion area 7b of the substrate 1. The insulating film 9 may, for example, be a silicon oxide film, obtained by the CVD method, or a silicon oxide film, obtained by thermal oxidation, that is, a thermally oxidized film (see FIG. 2).

The control gates 11 control the channel of an area between the select gate 3a and the first diffusion area 7a (or second diffusion area 7b). The control gates 11 are extended in a direction orthogonal to the comb-tooth-like protrusions (bands) of the select gates 3a and three-dimensionally cross the comb-tooth-like protrusions of the select gates 3a with an overpath (see FIGS. 1 and 2). In a three-dimensional crossing area of the control gates 11 with the select gates 3a, the control gates 11 abut against the upper surface of the insulating film 8 provided as an upper layer of the select gate 3a (see FIG. 2). On both sides of the select gates 3a, the control gates 11 are provided on the substrates with the interposition of the insulating film 5, floating gates 6a and the insulating film 8 (see FIG. 2). The control gates 11 are an electrically conductive film of polysilicon, for example. The surface of the control gates 11 may be provided with silicide of a high melting metal, not shown, in order to provide for a lower resistance.

The third diffusion area 21 is an n⁺ diffusion area operating as a source area and as a drain area of the cell transistor, during recording and readout, respectively (see FIG. 1). The third diffusion area 21 is extended in a direction orthogonal to the comb-tooth-like protrusions (bands) of the select gate 3a outside the cell area and three-dimensionally crosses the select gate 3a with an underpass. At the area of crossing the select gate 3a, the third diffusion area 21 is formed, in a manner not shown, on an upper surface of the substrate 1 directly below the insulating film 2 that is provided as a directly underlying layer of the select gate 3a.

Meanwhile, the operations for recording, readout and erasure of the semiconductor memory device of the first embodiment are the same as those of Example 2 of the related art.

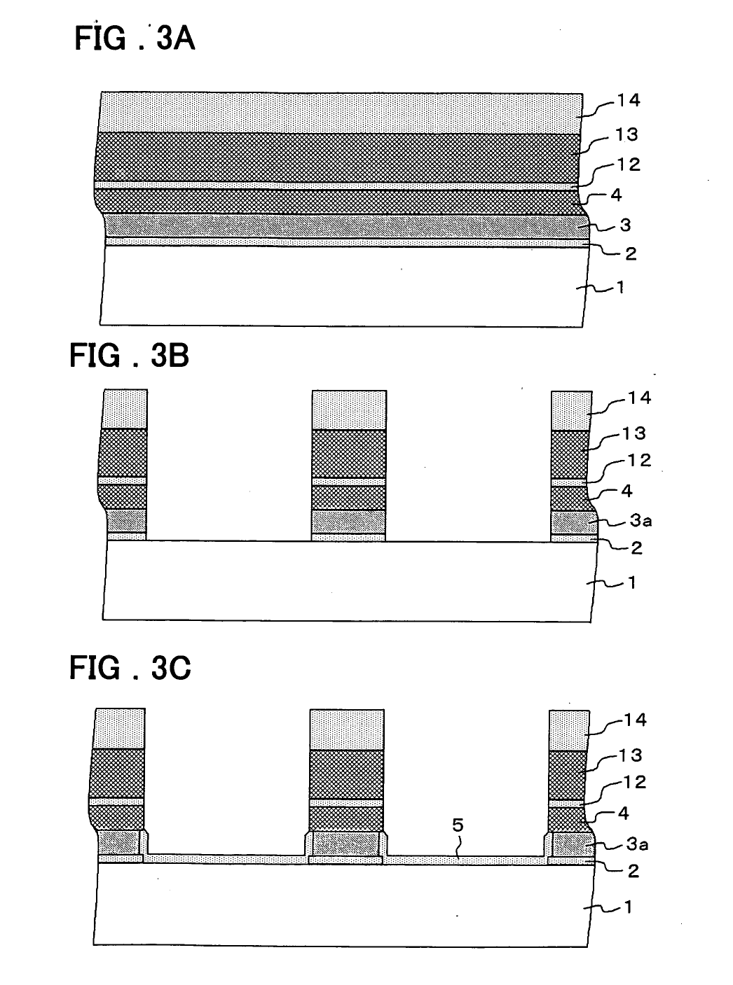

The method for producing the semiconductor memory device of the first embodiment of the present invention will now be described with reference to the drawings. FIGS. 3A to 6L are cross-sectional views for schematically illustrating the process steps of the method for producing the semiconductor memory device of the first embodiment of the present invention.

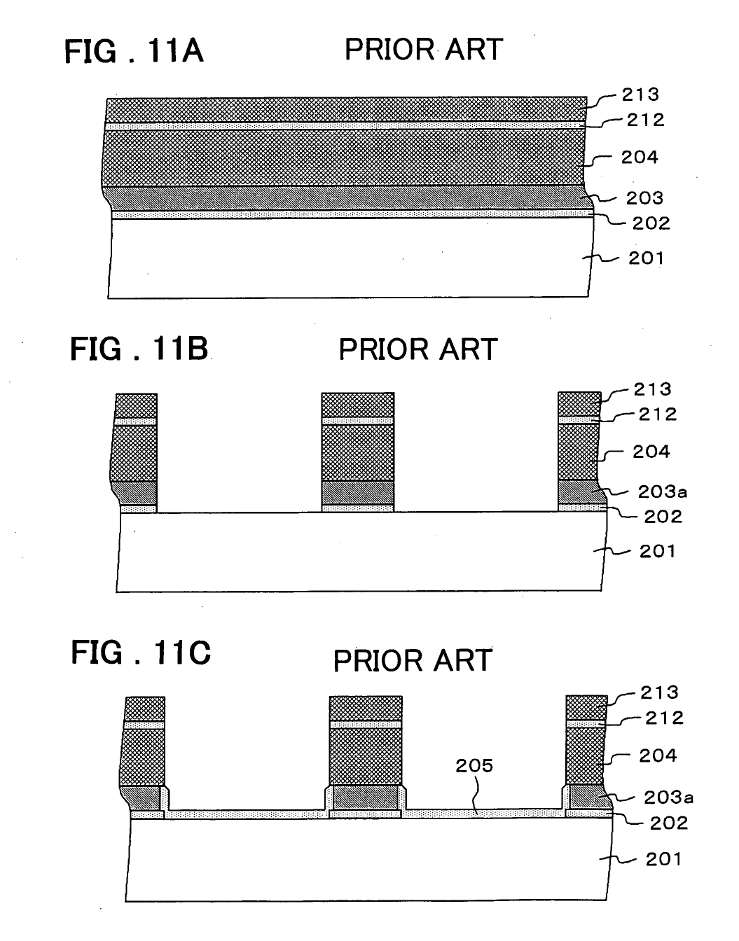

Initially, a device isolation layer, not shown, is provided on a substrate 1 and thereafter a well, not shown, is formed in a cell area of the substrate 1. A third diffusion area (21 of FIG. 1) is then formed, and thereafter a (first) insulating film 2, such as a silicon oxide film, is formed on the substrate 1. A select gate film 3, such as a polysilicon film, is formed on the insulating film 2. A insulating film 4, such as a silicon nitride film, is formed on the select gate film 3. An insulating film 12, such as a silicon oxide film, is formed on the insulating film 4, and an insulating film 13, such as a silicon nitride film, is formed on the insulating film 12. An insulating film 14, such as a silicon oxide film, is formed on the insulating film 13 in step B1 of FIG. 3A. The insulating film 4 later becomes a cap film of the select gate (3a of FIG. 2). The insulating film 13 later becomes a CMP stopper film. The insulating film 14, not provided in Example 2 of the related art (see FIG. 11A), is used for gaining in the height of the floating gate (6a of FIG. 2). The insulating film 12 operates as an etching stopper in case the insulating films 4, 13 are formed of the same material.

A photoresist, not shown, for forming the select gate 3a then is formed on the insulating film 14, and using the photoresist as a mask, the insulating films (i.e., fifth, fourth, third and second insulating films) 14, 13, 12 and 4, select gate film (3 of FIG. 3A) and the (first) insulating film 2 are selectively etched to form the select gate 3a. Subsequently, the photoresist is removed (step B2 of FIG. 3B).

A (sixth) insulating film 5, such as a silicon oxide film, then is formed on exposed surfaces of at least the substrate 1 and (side surfaces of) the select gates 3a in step B3 of FIG. 3C.

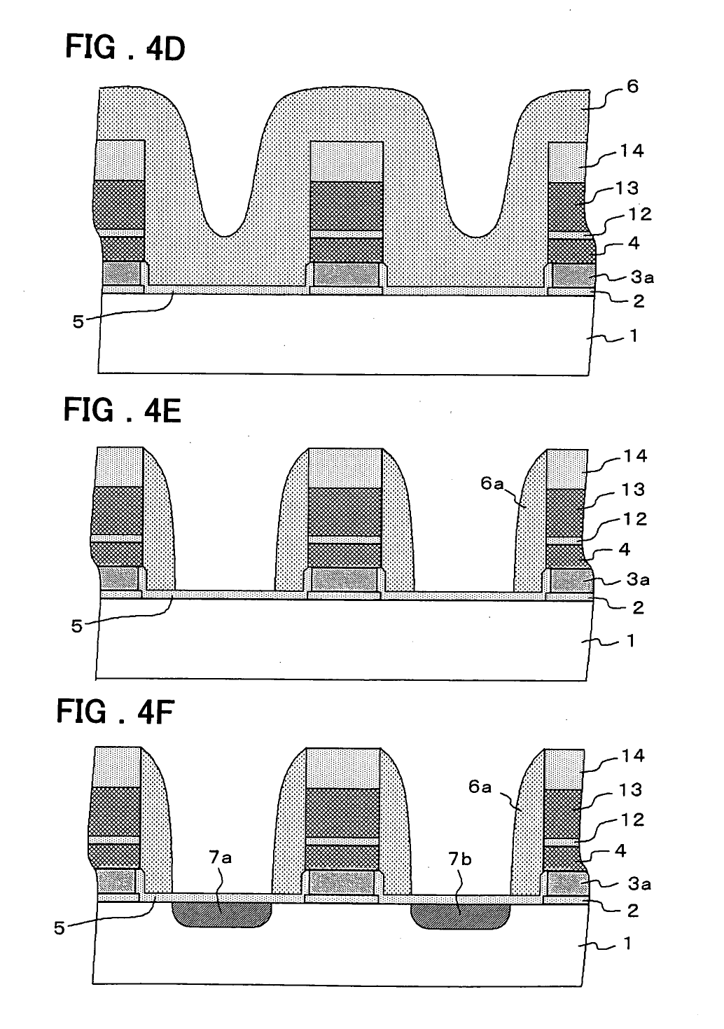

A floating gate film 6, such as a polysilicon film, then is deposited on the entire substrate surface, in step B4 in FIG. 4D.

The sidewall-shaped floating gates 6a are then formed at sidewall sections of the select gate 3a and the insulating films 4, 12, 13 and 14, by etchback of the floating gate film (6 of FIG. 4D), in step B5 of FIG. 4E.

Then, ions are implanted into the substrate 1, using the insulating film 14 and the floating gate 6a as masks, to form the first diffusion area 7a and the second diffusion area 7b in self-aligned fashion, in step B6 of FIG. 4F.

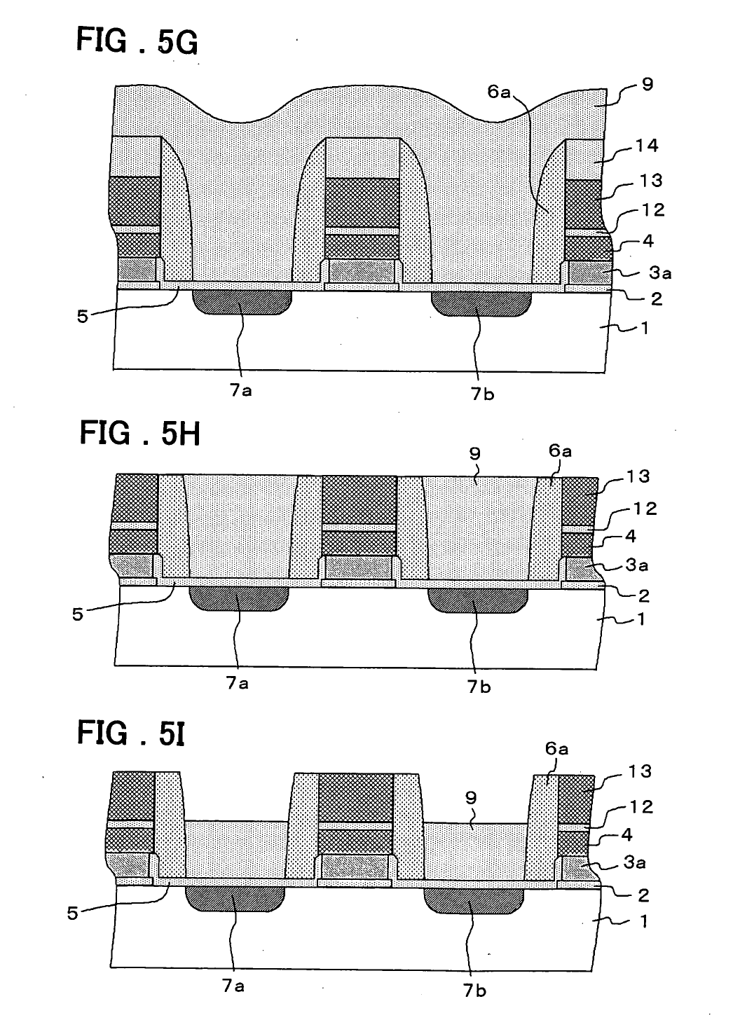

A (seventh) insulating film 9, such as a CVD silicon oxide film, then is deposited on the entire substrate surface, in step B7 of FIG. 5G.

The upper surfaces of the (seventh)insulating film 9 and the floating gate 6a are then planarized, by the CMP method, using the (fourth) insulating film 13 as a CMP stopper, in step B8 of FIG. 5H. At this time, the (fifth) insulating film 14 is removed in its entirety. The upper end faces of the floating gates 6a are uniformed to the same height and become approximately parallel to the upper surface (the upper major surface) of the substrate 1.

The (seventh) insulating film 9 is selectively removed in part in step B9 of FIG. 5I. Meanwhile, the (seventh) insulating film 9 is preferably removed, in part, by wet etching, in order to prevent the upper end face of the floating gates 6a from becoming damaged.

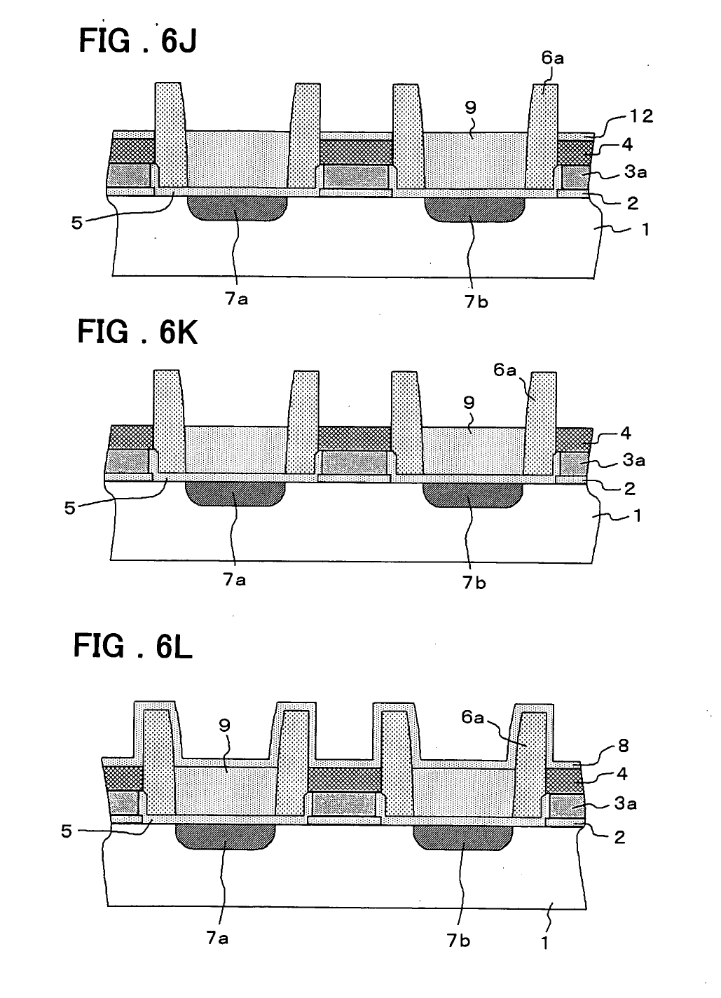

The (fourth) insulating film (13 of FIG. 5I) then is selectively removed in step B10 of FIG. 6J. Meanwhile, the (fourth) insulating film 13 is preferably removed by wet etching in order to prevent the upper end face of the floating gates 6a from becoming damaged.

The (third) insulating film 12, inclusive of the (seventh) insulating film 9, is selectively removed in step B11 of FIG. 6K. Meanwhile, the (third) insulating film 12 is preferably removed by wet etching in order to prevent the upper end face of the floating gates 6a from becoming damaged.

An (eighth) insulating film 8, such as an ONO film, is then formed on the entire substrate surface, in step B12 of FIG. 6L.

The control gate film of, for example, polysilicon, is then deposited on the entire substrate surface, and a photoresist, not shown, for forming a word line, is formed. Using the photoresist as a mask, the control gate film, insulating film 8 and the floating gate 6a are selectively removed (etched) to form the band-shaped control gates 11 and the island-shaped floating gates 6a. The photoresist then is removed in step B13 of FIG. 2. This completes a semiconductor memory device with planarized upper end faces of the floating gates 6a.

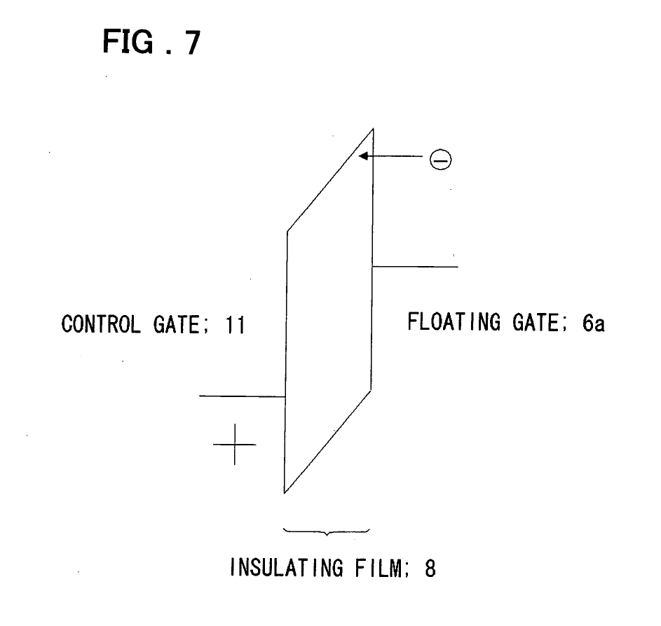

With the first embodiment, in which the upper end faces of the floating gates 6a have been planarized, the (eighth) insulating film 8 may be improved in reliability. In addition, the variations in the cross-sectional shape and height of the floating gates 6a, otherwise caused by etchback, may be diminished to reduce the variations in the cell capacitance ratio otherwise caused by manufacture tolerances. In particular, since the acute upper end part of the floating gate 6a, subjected most strongly to damages, ascribable to etchback, may be removed, the variations in the cell capacitance ratio, otherwise caused by manufacture tolerances, may appreciably be diminished. Furthermore, since the upper end faces of the floating gates 6a have been planarized, there is no fear of concentration of the electrical field in an area between the floating gates 6a and the control gates 11, even in case a readout voltage (e.g., high positive voltage) is applied to the control gates 11. Thus, no electrons are extracted from the floating gates 6a (see FIG. 7), thereby improving the operational reliability.

It should be noted that other objects, features and aspects of the present invention will become apparent in the entire disclosure and that modifications may be done without departing the gist and scope of the present invention as disclosed herein and claimed as appended herewith.

Also it should be noted that any combination of the disclosed and/or claimed elements, matters and/or items may fall under the modifications aforementioned.

What is claimed is:

1. A method for producing a semiconductor memory device comprising:
forming a sidewall-shaped floating gate at a sidewall of a select gate on a substrate, via an insulating film; and
planarizing an upper end of said floating gate.

2. The method for producing a semiconductor memory device according to claim 1 wherein, in said floating gate forming step, each one of a plurality of the select gates is formed via a first insulating film on said substrate; second, third, fourth and fifth insulating films are formed in this order on each one of said select gates when looking from the bottom towards above; a second semiconductor film is deposited on a sixth insulating film formed in an area of said substrate defined between two neighboring ones of the select gates and on sidewall surfaces of the two neighboring ones of the select gates; a plurality of sidewall-shaped floating gates are formed by etchback on both sides of at least the fifth, fourth, third and second insulating films and on both sides of said select gates; and wherein
said fifth insulating film is removed in said step of planarizing the upper ends of said floating gates.

3. The method for producing a semiconductor memory device according to claim 2, wherein the method includes, before the forming step of said floating gates,
forming a first insulating film, a first semiconductor film, a second insulating film, a third insulating film, a fourth insulating film and a fifth insulating film, on said substrate, in this order, when looking from the bottom towards above;
selectively etching said fifth insulating film, fourth insulating film, third insulating film, second insulating film and the first insulating film, in a preset area, to form said select gate; and
forming said sixth insulating film at least in an area of said substrate defined between neighboring ones of said select gates and on sidewall surfaces of said select gates;
the method also comprises, between the forming step of said floating gates and said planarizing step of the upper ends of said floating gates:
forming self-aligned first and second diffusion areas, on the surface of said substrate, by ion implantation, using said fifth insulating film and said floating gate as masks; and
embedding a seventh insulating film in an area between said neighboring ones of the floating gates, on the top of said first and second diffusion areas; and
the method further comprises, after said planarizing step of the upper end of said floating gate:
removing said fourth insulating film and the third insulating film;
forming an eighth insulating film on the entire substrate surface; and
forming a control gate on said eighth insulating film.

4. The method for producing a semiconductor memory device according to claim 2, wherein, in said planarizing step of the upper end of said floating gate, the upper end faces of said seventh insulating film and the floating gate are planarized by a CMP method, with said fourth insulating film as a CMP stopper.

5. A semiconductor memory device comprising:
a select gate arranged in a first area on a substrate;
first and second floating gates arranged in a second area adjacent to said first area;
first and second diffusion areas arranged in a third area adjacent to the second area; and
a control gate arranged on the top of said first and second floating gates; wherein
upper end faces of the first and second floating gates have a flat surface.

6. The semiconductor memory device according to claim 5 wherein
said first and second floating gates include sidewall surfaces formed by etchback; and wherein
the upper end faces of the first and second floating gates are planarized by CMP.

7. The semiconductor memory device according to claim 5 wherein
the upper end faces of said first and second floating gates are formed to a same and unified height and are formed so as to be substantially parallel to a major surface of said substrate.

8. The semiconductor memory device according to claim 6 wherein
among said sidewall surfaces of said floating gates, the side wall surfaces formed by etchback are shaped substantially orthogonal to a major surface of said substrate.
